(19) United States
(12) Patent Application Publication
(10) Pub. No.: US 2009/0289816 A1
(43) Pub. Date: Nov. 26, 2009

(54) One-handed computer input device comprising finger array input controls

(76) Inventor: Jeremy Kahsen, Woodridge, IL (US)

Correspondence Address: Jeremy Kahsen, 3197 Fox Ridge Court, Woodridge, IL, 60517, US

(21) Appl. No.: 12/099,760

(22) Filed: May 20, 2008

(51) Int. Cl. H03K 17/94

(52) U.S. Cl. 341/22

(57) ABSTRACT

The invention uses multidirectional fingertip controlled arrays to condense a typical keyboard into a one-handed device. Pointer control may additionally be added in a variety of ways to impart full computer control with just one hand.

### CROSS-REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

The invention relates to the field of computer input devices or typing machines. This device condenses the entire keyboard into four or five fingertip multi-directional arrays.

This invention addresses the need to switch between the keyboard and mouse or other peripheral.

This invention addresses the need for smaller typing methods for mobile devices.

This invention can allow people with a disabled hand to normally operate a computer.

Computer interface devices need a redesign. The original keyboard was designed over 130 years ago for use with mechanical typewriters. It was never designed for touch-typing. The mouse was added in the 1970s and cannot be used without interrupting normal typing. Today we are constantly switching between these two devices which have never been designed to work the way we use them.

Some new designs are being tried, but they are typically different versions of the QWERTY keyboard, use chording (hitting multiple keys to produce a single character), or simply attach the mouse to the keyboard in some fashion.

This invention was designed from scratch, without any preconceived notions, to meet today's demands with today's technology.

The closest competitor concept is the DataHand U.S. Pat. No. 5,743,666. However, this device still tries to conform to the QWERTY standard, uses keys, and requires two hands. It does not allow the space savings of this design, nor the ability to quickly type by rolling through common letter combinations.

### BRIEF SUMMARY OF THE INVENTION

This invention uses multi-directional arrays to input keyboard information. There will be one switch for each finger possibly including the thumb. These switches each have eight directional inputs plus one down-push input. Chaining is not used, but one finger can be used to switch modes. A mode would be equivalent to a shift or control button on a standard keyboard. The inputs can be any input including macros. Typing may be done by sweeping around the edge of an input array. This can allow users to enter multiple letters with one motion increasing speed. With four fingers, typing inputs and one finger switching modes there are 324 different input possibilities. There are more than enough inputs to put the entire power of a keyboard in one hand.

With all the typing controlled by one hand, the other hand is free for other tasks including the operation of other peripheral devices such as mice and joysticks. Less room is needed for the one-handed device making it suitable for mobile devices. People with only one functional hand can type.

### BRIEF DESCRIPTION OF THE SEVERAL VIEWS OF THE DRAWING

FIG. 1 is a top view of a prototype device. Input arrays (1) are arranged across the top of the device one for each finger. An additional input array (4) is mounted on an incline on the side of the device. A typical mouse wheel (2) is placed between the arrays for the index and middle fingers. Left and right mouse click buttons (3) are placed by the index and middle fingers respectively.

FIG. 2 is a side view of the device. (2) and (4) correspond with (2) and (4) for FIG. 1 The upper unit of the device (5) slides across the base of the device (6). A potentiometer (7) detects the positional relationship between (5) and (6).

FIG. 3 is a top view of a switch to be used in the arrays of (1) and (4) FIG. 1. The switch will have 8 directional inputs and an additional press input.

FIG. 4 is side view of the switch described in FIG. 3.

FIG. 5 is an alternative switch array. The switch will have a center input with 8 directional inputs surrounding it.

FIG. 6 is the input configuration for the input arrays. One array works as the mode selector for the device. The inputs for the rest of the arrays according to their mode are shown. The first row is the default mode. The top left array is the mode selector array. Blank input spaces are customizable.

### DETAILED DESCRIPTION OF THE INVENTION

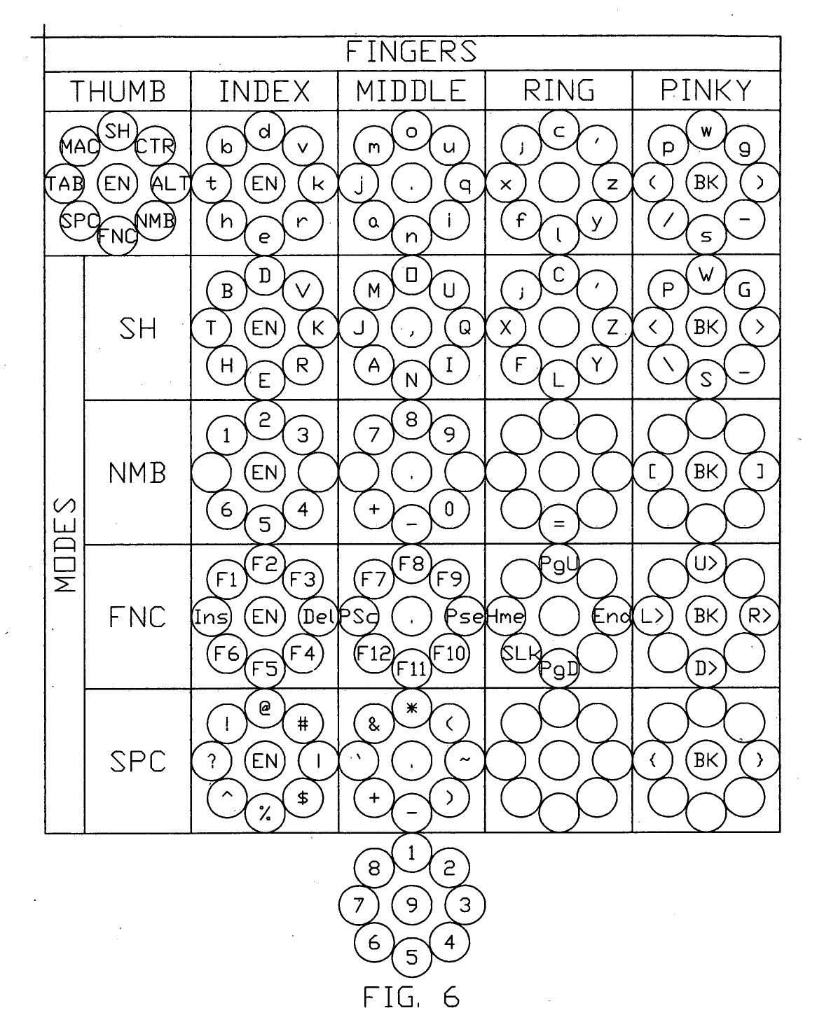

In operation, the device performs all the typing functions of a keyboard in addition to mouse control. The hand will be supported ergonomically on some housing with the arrays being positioned for comfortable use. The electronics will be hidden inside the housing. Typing is controlled through the input arrays. Fingers rest on a pad that moves horizontally and downward. Pressing the pad downward activates its center input from FIG. 6, moving the pad horizontally activates the input that is in the same direction as the movement as shown on FIG. 6. Note that the center does not have to be returned to after an input. The finger could stay still producing a double input or move directly to an adjacent input. By placing commonly used letter pairs next to each other, a user can often type two or more letters of a word with one circular stroke. Look at the placement of “t” “h” and “e” in FIG. 6, “the” can be typed as one stroke. This will enable typing speeds on this invention to be much greater. Using potentiometers with a center push for the arrays will allow the user to configure the areas input and include dead areas to avoid accidental inputs. There is one input array for each finger including the thumb. Each array has nine inputs. Modes can be entered for a single input by selecting the mode input once. Double selecting a mode locks it until another mode selection is made. If a mode is locked and it is selected again, the default mode is activated. Also when CTRL, ALT, or SH (shift) is pressed, modes add the new mode to the previous one. In this way, combinations such as CTRL+SH and CTRL+SH+ALT can be made. Using the modes in conjunction with the layout in FIG. 6 enables the user to perform all keyboard functions.

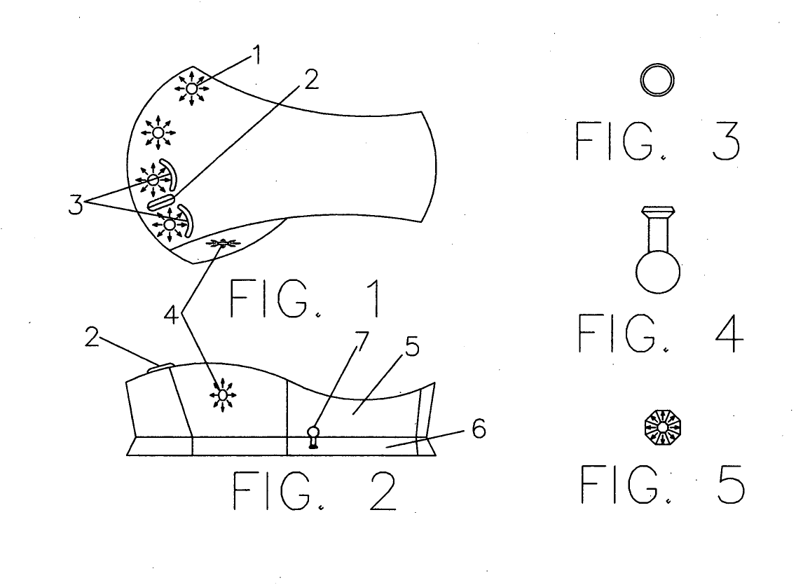

Pointer control is accomplished with a potentiometer that senses the relative position of the upper unit and the base see FIG. 2. Moving the upper unit in a direction causes the pointer to move in that direction. The farther from center the top unit is the faster the pointer speed will be. There are also mouse click buttons and a mouse wheel incorporated into the device.

The device will be ergonomic with left and right hand versions. Learning to use this device with the off-hand and freeing up the dominant hand for other tasks is the optimum choice. The finger pad of the arrays will provide enough friction to allow easy directional use through shape design or material selection.

The device will have the possibility of being customizable. The configuration in FIG. 6 could be completely changed. For example, all the center inputs could be shifts spreading the mode controls among all fingers.

The above describes the invention in one possible setting of use. Various modifications, additions and alterations may be made to the invention by one skilled in the art without departing from the spirit and scope of the invention as defined in the appended claims. The invention is using multidirectional arrays to replace the keyboard for sending data and commands to a computer in a compact and easy to use manner. Some form of moveable fingertip pads along with the electronics they activate are the essence of this invention.

The embodiments of the invention in which an exclusive property or privilege is claimed are defined as follows:

1. A computer input device comprising of a plural of fingertip-controlled arrays comprising of a fingertip contact surface, or pad, which can be actuated by the finger in a plural of directions to generate a plural of inputs corresponding to said actuating, the combined inputs from said arrays consisting of an entire alphabet or shorthand equivalent.

2. The computer input device defined in claim 1 consisting of a one-handed device.

3. The computer input device defined in claim 2 comprising of five arrays that comprise of 8 directional sliding or pivoting inputs and one center push input.

4. The computer input device defined in claim 2 comprising of four arrays that comprise of 8 directional sliding or pivoting inputs and one center push input.

5. The computer input device defined in claim 1 comprising of one or more pointer control systems.

6. The computer input device defined in claim 2 comprising of one or more pointer control systems.

7. The computer input device defined in claim 3 comprising of one or more pointer control systems.

8. The computer input device defined in claim 4 comprising of one or more pointer control systems.
